(19) United States
(12) Patent Application Publication
(10) Pub. No.: US 2026/0271647 A1
(43) Pub. Date: Sep. 10, 2026

(54) MANUFACTURING METHOD OF SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Hiroyuki TAKAHATA, Nisshin-shi (JP); Yuji NAGUMO, Nisshin-shi (JP); Masashi UECHA, Nisshin-shi (JP)

(21) Appl. No.: 19/657,397

(22) Filed: Apr. 24, 2026

Related U.S. Application Data
(63) Continuation of application No. 18/156,682, filed on Jan. 19, 2023, now Pat. No. 12,642,029.

(30) Foreign Application Priority Data
Feb. 22, 2022 (JP) 2022-025770

(51) Int. Cl. H10P 52/00; H10P 72/70

(52) U.S. Cl. CPC H10P 52/00; H10P 72/7402; H10P 72/7416; H10P 72/7422

(57) ABSTRACT

A manufacturing method of a semiconductor device, includes: preparing a wafer having a first surface on which a plurality of semiconductor elements is formed and to which a support plate is attached through an adhesive; grinding a second surface of the wafer opposite to the first surface in a state where the support plate is attached to the first surface of the wafer; forming a vertical crack inside the wafer and along a boundary between the adjacent semiconductor elements by pressing a scribe wheel against the wafer along the boundary; separating the support plate from the wafer while leaving the adhesive on the first surface of the wafer; cleaving the wafer along the boundary by pressing a breaking bar against the wafer over the adhesive and along the boundary; and removing the adhesive from at least one of the semiconductor elements divided from the wafer by the cleaving.

### CROSS REFERENCE TO RELATED APPLICATIONS

The present application is a continuation application of U.S. Utility Application No. 18/156,682 filed on Jan. 19, 2023, which claims the benefit of priority from Japanese Patent Application No. 2022-025770 filed on Feb. 22, 2022. The entire disclosures of the above applications are incorporated herein by reference.

### TECHNICAL FIELD

The present disclosure relates to a manufacturing method of a semiconductor device.

### BACKGROUND

It is known a manufacturing method of a semiconductor device including a process of individually cutting out semiconductor elements from a wafer on which multiple semiconductor elements are formed. For example, a wafer is cut (diced) along a boundary between adjacent semiconductor elements. Also, a method called a scribing and breaking process is known.

### SUMMARY

The present disclosure describes a manufacturing method of a semiconductor device, which is capable of reducing damage to a wafer.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a plan view of a wafer;

FIG. 2 is a diagram illustrating a part of a grinding process;

FIG. 3 is a diagram illustrating another part of the grinding process subsequent to the process illustrated in FIG. 3;

FIG. 4 is a diagram illustrating a scribing process;

FIG. 5 is a diagram illustrating a part of a support plate separating process;

FIG. 6 is a diagram illustrating another part of the support plate separating process subsequent to the process illustrated in FIG. 5;

FIG. 7 is a diagram illustrating a breaking process; and

FIG. 8 is a diagram illustrating a removing process.

### DETAILED DESCRIPTION

To begin with, a relevant technology will be described only for understanding the embodiments of the present disclosure.

As a part of manufacturing method of a semiconductor device, a scribing and breaking process is known. In the scribing and breaking process, a scribe wheel, which is a disk with a thin peripheral edge, is first pressed against a wafer along a boundary between adjacent semiconductor elements to generate a crack inside the wafer along the boundary. Since the crack extends in a direction perpendicular to a surface of the wafer, the crack will be referred to as a vertical crack. Next, a breaking bar is pressed along the boundary to cleave the wafer along the boundary. The scribing and breaking process can reduce a width between the adjacent semiconductor elements in the wafer, as compared to that in a case of the conventional dicing process.

In a process of forming semiconductor elements on a wafer, main structures, such as trenches and electrodes, which realize the functions of the semiconductor elements, are formed on a surface layer of a first surface of the wafer, and a second surface of the wafer is ground. Generally, the main structures are formed on the first surface of the wafer, and then the second surface of the wafer is ground. In a process of grinding the second surface of the wafer, an adhesive is applied to the first surface of the wafer and the support plate is attached to the first surface of the wafer through the adhesive. Since the main structures for realizing the functions of the semiconductor elements have been formed on the first surface, the adhesive is applied to the first surface with a relatively large thickness and the wafer is attached to the support plate through the adhesive. Such a thick adhesive layer also serves as a protective layer to protect the main structures on the first surface of the wafer. However, if it is tried to peel off the thick adhesive layer from the wafer after the vertical crack is formed in the wafer, a relatively large stress is likely to be generated inside the wafer due to the stickiness of the adhesive. If the vertical cracks are expanded further, there is a fear that the wafer will be damaged.

According to an aspect of the present disclosure, a manufacturing method of a semiconductor device, includes: preparing a wafer having a first surface on which a plurality of semiconductor elements is formed and to which a support plate is attached through an adhesive is prepared; grinding a second surface of the wafer opposite to the first surface to which the support plate is attached is ground; forming a vertical crack inside the wafer along a boundary between the adjacent semiconductor elements by pressing a scribe wheel against the wafer along the boundary; separating the support plate from the wafer while leaving the adhesive on the first surface of the wafer; cleaving the wafer along the boundary by pressing a breaking bar against the wafer over the adhesive and along the boundary; and removing the adhesive from at least one of the semiconductor elements that has been divided from the wafer by the cleaving.

In such a manufacturing method, the wafer is cleaved by pressing the breaking bar against the wafer over the adhesive without removing the adhesive from the first surface, that is, in the state where the adhesive is left on the first surface. The adhesive is removed after the semiconductor element is divided from the wafer. Therefore, since the wafer has been already cleaved along the vertical crack when the adhesive is removed, it is less likely that the vertical crack will expand further when the adhesive is removed.

As an embodiment of the present disclosure, a manufacturing method of a semiconductor device will be described hereinafter with reference to the drawings.

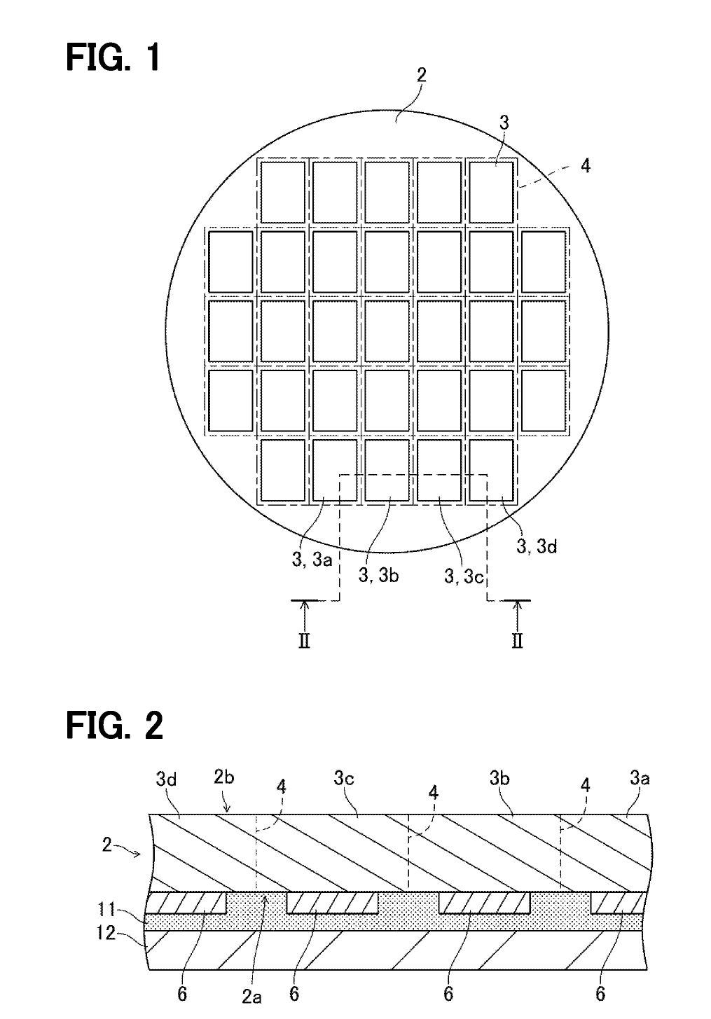

FIG. 1 is a plan view of a wafer 2 on which multiple semiconductor elements 3 are formed in a grid pattern. In FIG. 1, the semiconductor element 3 is schematically represented by a solid-line rectangle. The reference numeral “3” has been omitted for some solid-line rectangles. For convenience of explanation, a dividing line which is a boundary between adjacent semiconductor elements 3 and which is used when dividing the wafer 2 into individual semiconductor elements 3 later is referred to as a scribe line 4. As an example, the scribe line 4 is not a line actually marked on the wafer 2, but is an imaginary line. Alternatively, the scribe line 4 may be an actual groove or an actual line actually drawn on the wafer 2 so as to be visually recognizable. In FIG. 1, the scribe line 4 is indicated by an alternate long and short dashed line. Each semiconductor element 3 divided out from the wafer 2 corresponds to a semiconductor device. The semiconductor element 3 is an element having a function such as a transistor or a diode.

The material of the wafer 2 may be a semiconductor material such as silicon carbide (SiC) or gallium nitride (GaN), but is preferably a semiconductor material having a crystal plane. The wafer 2 is formed such that the crystal plane is perpendicular to a surface of the wafer 2. The semiconductor elements 3 are formed such that the scribe line 4, which is the boundary between adjacent semiconductor elements 3, coincides with the crystal plane in a plan view of the wafer.

A manufacturing method of a semiconductor device corresponding to the semiconductor element 3 will be described with reference to FIGS. 2-8. Note that FIGS. 2-8 each illustrate a cross section taken along line II-II of FIG. 1. For convenience of explanation, the semiconductor elements laid on the line II-II in FIG. 1 are referred to as semiconductor elements 3a, 3b, 3c and 3d from the left.

In the embodiment, the manufacturing method includes a grinding process, a scribing process, a support plate separating process, a breaking process, and a removing process.

### Grinding Process

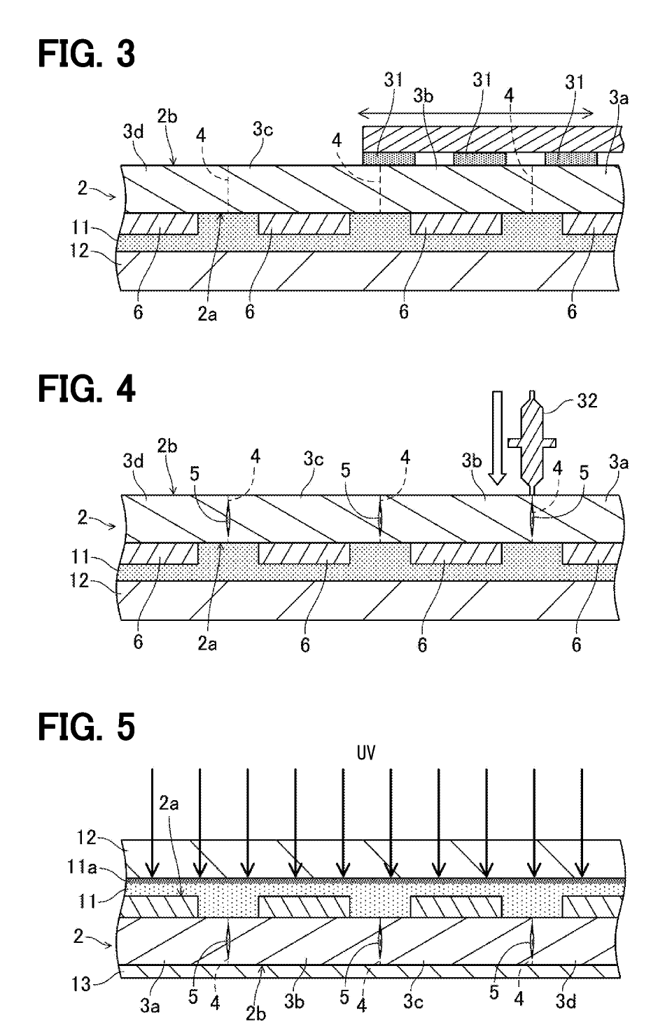

The grinding process will be described with reference to FIGS. 2 and 3. The wafer 2 has a first surface 2a and a second surface 2b opposite to the first surface 2a. Main structures 6 of the semiconductor elements 3a and 3b, such as gates and channels, are formed on a surface layer of the wafer 2 on the first surface 2a side. The wafer 2 is thinned later. That is, in FIG. 2, the wafer 2 is shown thicker than that in FIG. 3 in order to indicate that the wafer 2 has not yet been thinned.

In FIGS. 2 and 3 (also FIG. 4, which will be described later), the wafer 2 is shown with the first surface 2a facing downward. The scribe line 4 is shown inside the wafer 2 by a dashed line. In FIG. 2, a part of the wafer 2 on the left side of a left scribe line 4 corresponds to the semiconductor element 3d, a part of the wafer 2 on the left side of a central scribe line 4 corresponds to the semiconductor element 3c. Also, a part of the wafer 2 on the right side of the central scribe line 4 corresponds to the semiconductor element 3b, and a part of the wafer 2 on the right side of the right scribe line 4 corresponds to the semiconductor element 3a. The semiconductor elements 3a to 3d will be collectively referred to as "semiconductor element 3" when they are explained without distinction.

Note that illustration and description of the specific internal structure of the semiconductor element 3 are omitted. In order to facilitate understanding in the drawings, the main structure 6 of the semiconductor element 3, which includes an essential part for realizing the function of the semiconductor element, is shown with a hatching different from a hatching of a rest part of the wafer 2. For example, the main structure 6 includes a channel, a gate electrode, and the like formed in the semiconductor element 3. The main structure 6 is formed at the surface layer of the wafer 2 on the first surface 2a side. On the second surface 2b side, either nothing or a simple structure such as an electrode is formed.

In the grinding process, the first surface 2a of the wafer 2 is attached to a support plate 12 through an adhesive 11, and the second surface 2b of the wafer 2 is ground by a grinding wheel 31, as shown in FIG. 3. The wafer 2 is thinned by grinding. In FIG. 3, the wafer 2 is thus thinner than that shown in FIG. 2.

The adhesive 11 is, for example, a silicon-based adhesive. The adhesive 11 has a function of adhering the wafer 2 to the support plate 12 as well as a function of protecting the main structure 6 formed on the first surface 2a side of the wafer 2. Therefore, the adhesive 11 is applied to have a relatively large thickness. Although not specifically illustrated, the first surface 2a side of the wafer 2 is uneven, that is, the wafer 2 has projections or recesses on the first surface 2a side due to the main structures 6 formed thereon. The adhesive 11 can enter into the recesses, and thus can closely adhere to the first surface 2a. Further, the adhesive 11 has a property that a surface layer thereof hardens and loses its stickiness when irradiated with ultraviolet rays.

### Scribing Process

Following the grinding process, a scribing process is performed. The scribing process will be described with reference to FIG. 4. The first surface 2a of the wafer 2 has been attached to the support plate 12 through the adhesive 11. In the scribing process, the wafer 2 is used in a state of being attached to the support plate 12. In the scribing process, a scribe wheel 32 is pressed against the wafer 2 from the second surface 2b side and along the scribe line 4, that is, along the boundary between the adjacent semiconductor elements 3 to form a vertical crack 5 inside the wafer 2 along the scribe line 4.

The wafer 2 is fixed to the support plate 12 with the adhesive 11 interposed therebetween. Therefore, even if the scribe wheel 32 is moved along the scribe line 4, the wafer 2 does not move. Further, even if the scribe wheel 32 is strongly pressed against the wafer 2, the adhesive 11 protects the main structures 6.

The scribe wheel 32 is a disc-shaped component and is pivotally supported by a support device (not shown). The scribe wheel 32 is moved along the scribe line 4 while being pressed against the wafer 2. During the movement, the scribe wheel 32 rolls over the wafer 2 without slipping like a tire rolling on a road surface. Although the scribe wheel 32 has a sharp peripheral edge, the scribe wheel 32 does not cut the wafer 2 and is only pressed against the wafer 2 from the second surface 2b side. As described above, the scribe line 4 extends along the crystal plane of the wafer 2. Thus, when the scribe wheel 32 is strongly pressed against the wafer 2, a vertical crack 5 is generated inside the wafer 2 along the scribe line 4. The “vertical crack” means a crack extending perpendicularly to the surface of the wafer 2. In other words, the vertical crack 5 extends along the crystal plane of the wafer 2.

### Support Plate Separating Process

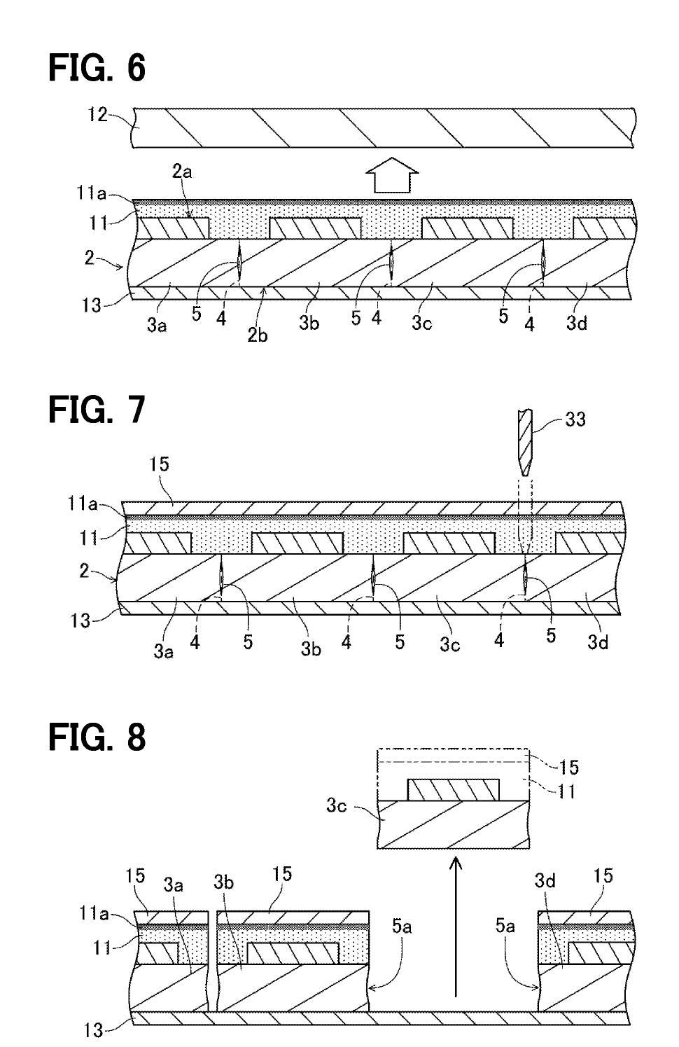

Following the scribing process, the support plate separating process is performed. The support plate separating process will be described with reference to FIGS. 5 and 6. It should be noted that, in FIG. 5 and subsequent drawings, the wafer 2 is illustrated with the first surface 2a facing up. Before separating the support plate 12, a dicing tape 13 is attached to the second surface 2b of the wafer 2, as shown in FIG. 5. Further, the wafer 2 is fixed to a dicing ring (not shown).

In the support plate separating process, the support plate 12 is separated from the wafer 2 while the adhesive 11 is kept on the wafer 2. As described above, when the adhesive 11 is irradiated with the ultraviolet rays, the surface layer 11a of the adhesive 11 is cured, and the surface of the surface layer 11a loses its adhesive force. Also, the support plate 12 is made of transparent glass. As shown by solid arrows in FIG. 5, the adhesive 11 is irradiated with the ultraviolet rays through the transparent support plate 12. As a result, the surface layer 11a of the adhesive 11 hardens and the surface of the surface layer 11a loses its adhesive property. Therefore, the support plate 12 is easily removed from the wafer 2, as shown in FIG. 6.

As the adhesive 11, a thermosetting adhesive may be used. In such a case, the support plate 12 may not be transparent. The support plate 12 may be separated from the adhesive 11 by heating the surface layer 11a of the adhesive 11 to lose its adhesive property.

### Breaking Process

Following the support plate separating process, the breaking process is performed. The breaking process will be described with reference to FIGS. 7 and 8. In the breaking process, a breaking bar 33 is pressed against the wafer 2 along the scribe lines 4 to cleave the wafer 2 along the scribe lines 4.

FIG. 7 shows a cross section before the breaking bar 33 is pressed against the wafer 2. As shown in FIG. 7, another protective sheet 15 is attached to the surface of the adhesive 11, that is, the surface of the surface layer 11a.

In FIG. 7, the breaking bar 33 pressed against the wafer 2 is illustrated with an imaginary line (i.e., chain double-dashed line). The breaking bar 33 has a length equivalent to the diameter of the wafer 2 and is pressed against the wafer 2 over the entire length of the scribe line 4. The vertical crack 5 has been formed along the scribe line 4 inside the wafer 2. When the breaking bar 33 is strongly pressed against the wafer 2, the vertical crack 5 extends further along the crystal plane and the wafer 2 is thus cleaved along the scribe line 4, as shown in FIG. 8. In FIG. 8, reference number “5a” denotes some traces of the vertical cracks 5.

The breaking bar 33 is pressed against the wafer 2 over the adhesive 11 and the protective sheet 15. When the breaking bar 33 is pressed, the wafer 2 is cleaved, and, at the same time, the adhesive 11 and the protective sheet 15 are also separated along the scribe line 4. FIG. 8 shows a cross section after the braking bar 33 is pressed against the wafer 2 so that the wafer 2 is cleaved along the scribe line 4 and the adhesive 11 and the protective sheet 15 are also separated. The wafer 2 is thus divided into individual semiconductor elements 3a to 3d.

### Removing Process

Following the breaking process, the removing process is performed. In the removing process, the adhesive 11 is removed from the semiconductor element 3 that has been divided from the wafer 2. FIG. 8 shows the semiconductor element 3c from which the dicing tape 13 has been peeled off, and the adhesive 11 and the protective sheet 15 have been removed. For example, the adhesive 11 is dissolved by a solvent and removed from the semiconductor element 3c. The adhesive 11 and protective sheet 15 are removed also from the other semiconductor elements 3a, 3b and 3d.

According to the manufacturing method of the embodiment described above, the vertical cracks 5 are formed inside the wafer 2 after the adhesive 11 is applied to the wafer 2, and the wafer 2 is divided into individual semiconductor elements 3 before the adhesive 11 is removed from the semiconductor elements 3. Therefore, it is possible to suppress the vertical crack 5 from expanding when the adhesive 11 is removed.

Other features of the manufacturing method of the embodiment are explained as follows. In the support plate separating process, the surface layer 11a of the adhesive 11 is cured to separate the support plate 12 from the adhesive 11. Thus, the support plate 12 can be easily removed. In addition, it is less likely that the breaking bar 33 will be contaminated with the adhesive 11 in the breaking process. That is, at least contamination of the breaking bar 33 with the adhesive 11 is reduced.

In the breaking process, after the protective sheet 15 is attached to the surface of the adhesive 11, the breaking bar 33 is pressed against the wafer 2. As such, the contamination of the breaking bar 33 with the adhesive 11 can be more effectively suppressed by the protective sheet 15.

Note that the protective sheet 15 may be omitted. In such a case, the adhesive 11 may be removed from the wafer 2 using a strong adhesive tape. That is, an adhesive tape may be attached to the surface of the adhesive 11 and the adhesive 11 may be peeled off from the wafer 2 together with the adhesive tape.

Points to note for the technique in the embodiment described above will be described. Neither the scribe wheel 32 nor the breaking bar 33 cuts the wafer 2. The scribe wheel 32 generates the vertical crack 5 inside the wafer 2, and the breaking bar 33 widens the vertical crack 5 to cleave the wafer 2. The scribe wheel 32 and breaking bar 33 may be made of any material and may have any shape as long as the functions described above are achieved.

The vertical crack 5 may reach one of the first surface 2a and the second surface 2b of the wafer 2.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A manufacturing method of a semiconductor device, comprising:
forming a vertical crack inside a wafer and along a boundary between a plurality of semiconductor elements formed directly on and in contact with a first surface of the wafer by pressing a scribe wheel against a second surface of the wafer from the second surface side along the boundary, the second surface being opposite to the first surface, the wafer having a support plate attached to the first surface through an adhesive that contacts the first surface;
separating the support plate from the wafer while leaving the adhesive on the first surface of the wafer;
cleaving the wafer along the boundary by pressing a breaking bar against the first surface of the wafer through the adhesive from the first surface side and along the boundary, thereby dividing the wafer along the boundary into a plurality of semiconductor devices; and
removing the adhesive from at least one of the semiconductor devices that has been separated from the wafer by the cleaving.

2. The manufacturing method according to claim 1, wherein
the separating of the support plate includes curing a surface layer of the adhesive, and separating the support plate from the adhesive.

3. The manufacturing method according to claim 1, wherein
the cleaving of the wafer along the boundary includes attaching a protective sheet on a surface of the adhesive before the pressing of the breaking bar.

4. The manufacturing method according to claim 2, wherein
the cleaving of the wafer along the boundary includes attaching a protective sheet on a surface of the adhesive before the pressing of the breaking bar.
